(19) United States
(12) Patent Application Publication
(10) Pub. No.: US 2002/0040991 A1
(43) Pub. Date: Apr. 11, 2002

(54) Variable capacitor for tuned circuits

(76) Inventors: Sherif Embabi, Plano, TX (US); Abdellatif Bellaouar, Dallas, TX (US)

Correspondence Address: TEXAS INSTRUMENTS INCORPORATED, P O BOX 655474, M/S 3999, DALLAS, TX, 75265

(21) Appl. No.: 09/866,334

(22) Filed: May 25, 2001

Related U.S. Application Data
(60) Provisional application No. 60/226,179, filed on Aug. 18, 2000.

(51) Int. Cl. H01L 29/76; H01L 27/108; H01L 29/94; H01L 31/036

(52) U.S. Cl. 257/312; 257/67; 257/68; 257/130; 257/206; 257/390

(57) ABSTRACT

A switched variable capacitor (20), and binary-weighted array (40) of such capacitors (20), are disclosed. The switched variable capacitor (20) includes a switching transistor (14) connected in series with first and second capacitors (12), between the two terminals (A,B). Bias transistors (18) are provided, and of opposite conductivity type as the switching transistor (14) but with their gates connected to the gate of the switching transistor (14). The bias transistors (18), when on, apply a reverse bias voltage to the source/drain regions of the switching transistor (14), to minimize the parasitic junction capacitance, and thus improve the temperature stability of the capacitor (20). A binary-weighted array (40) of switched variable capacitors (20) is also disclosed, as is a voltage-controlled oscillator (50) incorporating such an array (40).

### CROSS-REFERENCE TO RELATED APPLICATIONS

This application claims priority, under 35 U.S.C. §119(e), of provisional application No. 60/226,179, filed Aug. 18, 2000.

### STATEMENT REGARDING FEDERALLY SPONSORED RESEARCH OR DEVELOPMENT

Not applicable.

### BACKGROUND OF THE INVENTION

This invention is in the field of integrated circuits, and is more specifically directed to variable capacitor circuits.

As well known in the art, variable capacitors are useful circuit elements in many applications. Communications systems, particularly those involving the generation and receipt of periodic signals, such as modulated radio signals, often involve the controlled tuning of circuits to particular frequencies. Variable capacitors are of course useful in such tuning. With the extremely high frequencies involved in modern communications, such frequencies ranging up to on the order of GHz, and also considering the narrow subchannels often used in broadband communications, the requirements for tuning accuracy and stability over temperature have become quite stringent.

Of course, most modern communications systems include tuning circuits that are realized in integrated circuits. Conventional variable capacitors in integrated circuits are realized as either bipolar or metal-oxide-semiconductor (MOS) varactors. These conventional varactors have to date been limited in their quality factor, narrow capacitance ratios (Cₘₐₓ/Cₘₐₓ), and significant temperature sensitivity. The capacitance of conventional MOS varactors also varies over time. Accordingly, conventional varactors for integrated circuits are not well-suited for the high demands of precision and stability desired for modern high-frequency communications systems such as wireless handsets.

According to another conventional approach, tuning circuits are implemented by way of an array of switched fixed capacitors. Typically, the array includes binary-weighted switched capacitors, with the overall capacitance of the array determined by a digital word that controls the interconnection of the capacitors. The interconnection among the binary-weighted capacitors is effected by switches, such as MOS transistors, that are controlled in response to the digital control word.

By way of background, attention is directed to FIG. 1 for a description of a well-known switched variable capacitor. According to this arrangement, two capacitors 2_{A}, 2_{B} are connected in series between terminals A, B, by way of transistor 4, which serves as a switch. In this example, transistor 4 is an enhancement-mode n-channel MOS transistor, connected as a pass gate. As such, capacitors 2_{A}, 2_{B} are connected to respective source/drain regions of transistor 4. A switching signal is applied to terminal SW and thus to the gate of transistor 4, selectively turning transistor 4 on and off, and thus selectively connecting and disconnecting capacitors 2_{A}, 2_{B}. The network of FIG. 1 therefore provides a variable capacitance, in that it can selectably provide, between terminals A, B, a maximum capacitance Cₘₐₓ and a minimum capacitance Cₘᵢₙ. In this example, maximum capacitance Cₘₐₓ is presented with transistor 4 on, and minimum capacitance Cₘᵢₙ is presented with transistor 4 off.

FIG. 2a schematically illustrates the maximum capacitance case in which transistor 4 is on, connecting capacitors 2_{A}, 2_{B} in series as shown. The maximum capacitance Cₘₐₓ between terminals A, B is thus simply the series capacitance:

$${C}_{max} = \frac{{C}_{A} {C}_{B}}{{C}_{A} + {C}_{B}}$$

$$\text{or, in the case where} {C}_{A} = {C}_{B} = C \text{:}$$

$${C}_{max} = \frac{C}{2}$$

FIG. 2b schematically illustrates the minimum capacitance case in which transistor 4 is off, disconnecting the capacitors 2_{A}, 2_{B} from one another, at least in the direct sense. As noted above, however, in this example, capacitors 2_{A}, 2_{B} each have a plate connected to a source/drain region of transistor 4. This connection gives rise to parasitic junction capacitances C_{jA}, C_{jB}, respectively, which couple capacitors 2_{A}, 2_{B} to ground, as shown in FIG. 2b, and thus to one another. Another source of parasitic capacitance is bottom capacitance C_{bA}, C_{bB} between the capacitor bottom plate and the underlying substrate. The overall parasitic capacitance Cp for each capacitor 2 is the sum Cₚ=Cⱼ+C_{b}; in this conventional arrangement, however, junction capacitance Cⱼ is much larger than the bottom capacitance C_{b}. Assume, for the sake of description, that C_{A}=C_{B}=C and that C_{pA}=C_{pB}=C_{P}. Considering these parasitic capacitances C_{pA}, C_{pB}, the minimum capacitance between terminals A, B, in the network of FIG. 1 is:

$${C}_{min} = \frac{{CC}_{p}}{2 ( C + {C}_{p} )}$$

Particularly in constructing a binary-weighted array of switched capacitors, for use in a tuning circuit, the range of each switched capacitor is an important parameter. For the variable capacitance network of FIG. 1, this range corresponds to the ratio Cₘₐₓ/Cₘᵢₙ, which (for C_{A}=C_{B}=C and that C_{pA}=C_{pB}=CP) is:

$$\frac{{C}_{max}}{{C}_{min}} = \frac{\frac{C}{2}}{\frac{{CC}_{p}}{2 ( C + {C}_{p} )}} = \frac{C + {C}_{p}}{{C}_{p}}$$

Accordingly, if the parasitic capacitance Cₚ is minimized, the range of the switched variable capacitor will be high.

However, another important parameter in switched capacitor networks, particularly those intended for use at high frequencies such as encountered in wireless communications, is the quality factor, or Q, of the capacitors. To obtain a high quality factor, the on resistance of transistor 4 should be as small as possible, which is accomplished by increasing the channel width/length ratio of the device. However, as the junction width increases, the parasitic junction capacitance Cₚ also increases, decreasing the tuning ratio Cₘₐₓ/Cₘᵢₙ. A tradeoff between quality factor and capacitance range results.

Another limitation of this conventional switched variable capacitor is the difficulty of properly biasing switching transistor 4. According to conventional arrangements, such as shown in FIG. 1, only the gate voltage (terminal SW) is controlled; no external bias is typically applied to the source/drain regions. This lack of bias can result in uncertainty of the state of the capacitor, if the source/drain regions float. In addition, because junction capacitance varies with the voltage across the junction, and because the parasitic junction capacitance is such an important factor in the performance of the network, it would be desirable to bias these junctions in such a manner as to minimize the parasitic capacitance Cₚ when transistor 4 is off. To preserve a reasonable quality factor for the case with transistor 4 is off, however, the bias of the source/drain junctions should be provided through resistors that are as large as possible. Such large bias resistors will not only occupy significant chip area, particularly in the fabrication of an array of switched capacitors, but may also introduce noise into the network, which is especially undesirable in high-frequency applications.

### BRIEF SUMMARY OF THE INVENTION

It is therefore an object of the present invention to provide a switched capacitor with a large maximum-to-minimum capacitance ratio, for use in a variable capacitor network.

It is a further object of the present invention to provide such a switched capacitor in which bias is provided to source and drain regions of the switching transistor, without adversely affecting the quality factor of the device, and without requiring large chip areas.

It is a further object of the present invention to provide such a switched capacitor that is especially well-suited for high-frequency applications, such as wireless broadband communications.

It is a further object of this invention to provide such a switched capacitor that is stable over temperature.

It is a further object of this invention to provide such a switched capacitor that is biased to have a maximum Q in its maximum capacitance state.

It is a further object of this invention to provide such a switched capacitor that is suitable for digital control, thus avoiding the necessity for precise analog control voltages.

Other objects and advantages of the present invention will be apparent to those of ordinary skill in the art having reference to the following specification together with its drawings.

The present invention may be implemented into a switched capacitor network, for selectively connecting or disconnecting two capacitors in series with one another. A switch field-effect transistor is provided in series with the capacitors. Two bias transistors are connected to each side of the switch transistor, to bias the source and drain of the switch transistor to a reference voltage when the switch capacitor is on. A pair of complementary bias transistors are also connected to each side of the switch transistor, to bias the source and drain of the switch transistor to a selected bias voltage, different from the reference voltage, when the switch capacitor is off. Junction parasitic capacitance at the switch device is minimized.

### BRIEF DESCRIPTION OF THE SEVERAL VIEWS OF THE DRAWING

FIG. 1 is an electrical diagram, in schematic form, of a conventional switched variable capacitor.

FIGS. 2a and 2b are electrical diagrams, in schematic form, of the conventional network of FIG. 1 in its on and off states, respectively.

FIG. 3 is an electrical diagram, in schematic form, of a switched variable capacitor according to the preferred embodiment of the invention.

FIG. 4 is an electrical diagram, in schematic form, of a switched variable capacitor array according to the preferred embodiment of the invention.

FIG. 5 is an electrical diagram, in block form, of a voltage controlled oscillator according to the preferred embodiment of the invention.

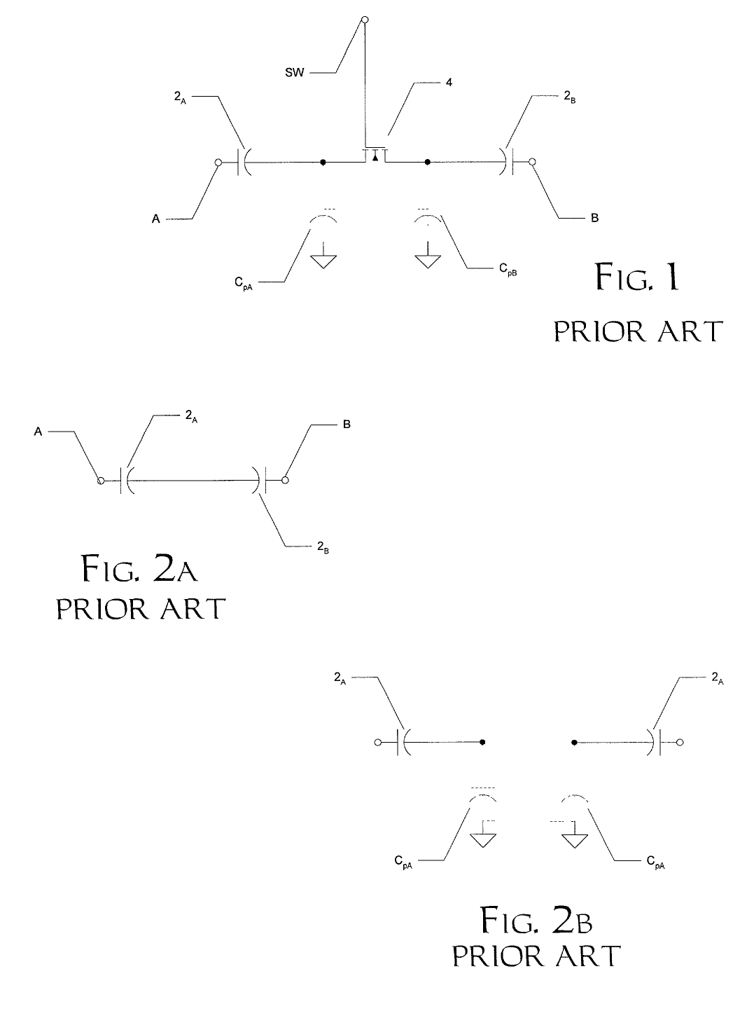

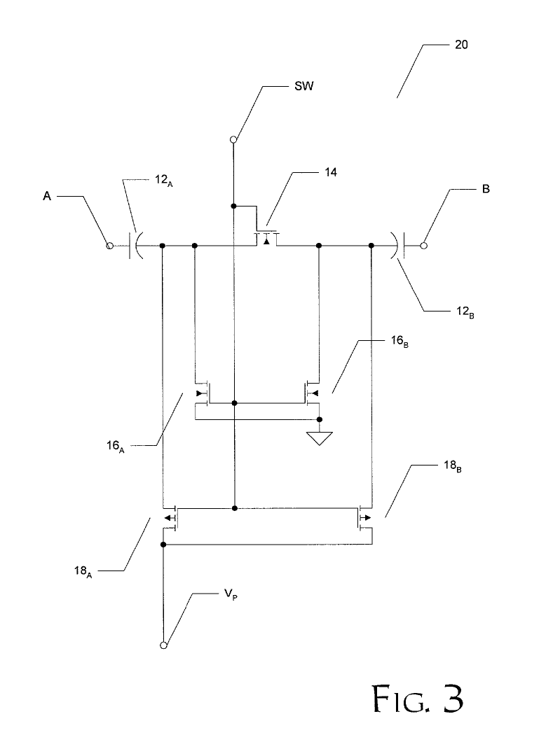

### DETAILED DESCRIPTION OF THE INVENTION

The present invention may be implemented in any circuit application in which a variable capacitor may be used, particularly a digitally controlled switched variable capacitor. An important application for variable capacitors are tuning circuits, in which the operation of a circuit is to be matched to a selected frequency by varying a capacitance in the circuit

In particular, the present invention is believed to be especially well-suited for use in connection with high-frequency, high-performance, phase-locked loops as used in the modulation of radio frequency communications signals in wireless telephone handsets. As is known in that art, high-frequency phase-locked loops are useful in producing stable modulated signals, such as frequency-shift-keyed (FSK) modulated signals. A fundamental building block in such phase-locked loops is the voltage-controlled oscillator (VCO), which generates a periodic signal at a frequency controlled by an error signal from a phase-frequency detector; this error signal corresponds to the difference between a reference clock and a feedback signal derived from the phase-locked loop output in combination with the signal to be communicated. A variable capacitance can be used in the VCO to control the frequency of its oscillation. It is contemplated that a binary-weighted array of switched variable capacitors constructed according to this invention will be especially beneficial when used as a variable capacitor in such high-performance VCOs and phase-locked loops. An example of such an application of the switched variable capacitor according to this invention will be described below.

Alternatively, this invention may be used in connection with variable capacitors in a wide range of applications. It is contemplated that those skilled in the art having reference to this specification will be readily able to implement this invention in such circuits and applications. It is therefore to be understood that the following description is provided by way of example only, and is not meant to limit the true scope of the invention as claimed.

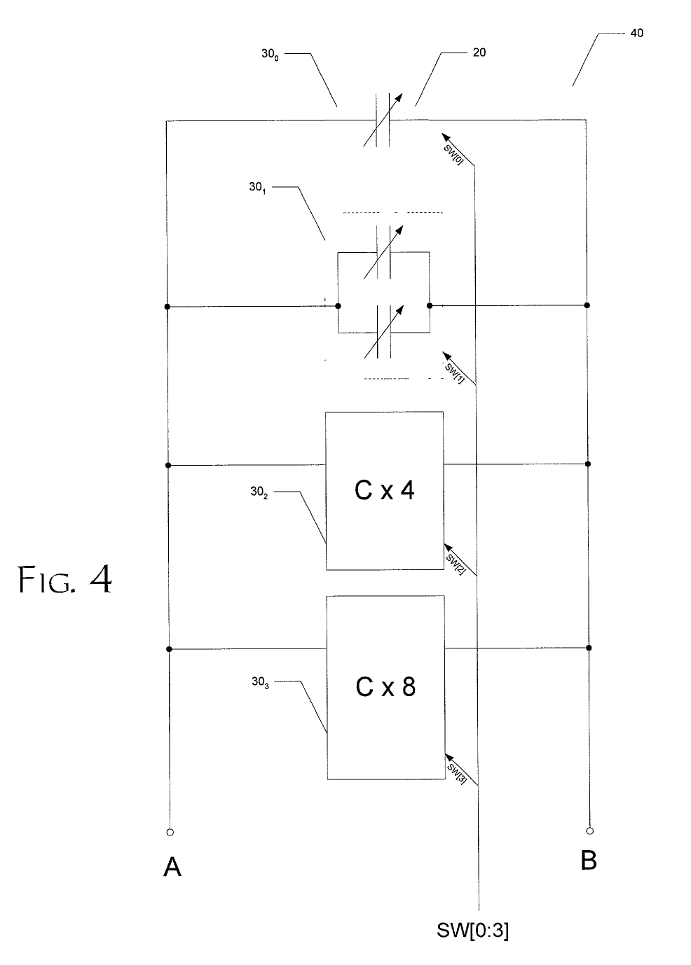

Referring now to FIG. 3, variable capacitor 20 according to the preferred embodiment of the invention includes capacitors 12_{A}, 12_{B}, connected to terminals A, B, respectively. Each of capacitors 12 may be constructed in the conventional manner for integrated circuit capacitors, examples of which include polysilicon-to-polysilicon thin film capacitors, polysilicon-to-diffusion capacitors, and the like. However, for purposes of temperature stability of capacitor 20 over temperature, capacitors 12 are preferably metal-to-metal capacitors.

Each of capacitors 12_{A}, 12_{B} are also connected to a source/drain region of transistor 14. As such, as shown in FIG. 3, switched variable capacitor 20 includes the series connection of capacitor 12_{A}, transistor 14, and capacitor 12_{B} between terminals A and B. The gate of transistor 14 receives a control signal from terminal SW. In this embodiment of the invention, transistor 14 is an n-channel enhancement-mode MOS transistor. In order to maximize the quality factor of variable capacitor 20, transistor 14 is preferably a relatively large device in terms of drive capability, having a relatively large channel width-to-length ratio (e.g., on the order of 20 or greater) so that its on-resistance is minimized. Transistor 14 may also be realized by way of two or more MOS transistors connected in parallel.

Bias transistors 16_{A}, 16_{B} are provided in switched variable capacitor 20 according to the preferred embodiment of the invention. According to this embodiment of the invention, bias transistors 16 are also n-channel enhancement-mode MOS transistors, although preferably having the minimum channel width available for the manufacturing technology (for example, having a width/length ratio of on the order of 1.5). The drain of transistor 16_{A} is connected to the source/drain region of transistor 14 at the point at which it is connected to capacitor 12_{A}, and the drain of transistor 16_{B} is connected to the source/drain region of transistor 14 at the point at which it is connected to capacitor 12_{B}. The sources of transistors 16 are both connected to a reference voltage, such as ground, and the gates of transistors 16 are connected together and to terminal SW to receive the switching control signal. According to this embodiment of the invention, because bias transistors 16 and switching transistor 14 are both n-channel devices, and have their gates connected in common, bias transistors 16 are turned on when transistor 14 is on, and off when transistor 14 is off. The bias to ground provided by transistors 16 ensures that the on-resistance of transistor 14 is minimized, maximizing the Q for switched variable capacitor 20 in its maximum capacitance state.

Switched variable capacitor 20 according to this embodiment of the invention also includes bias transistors 18_{A}, 18_{B} for biasing the source/drain regions of transistor 14 when the device is off. In this preferred embodiment of the invention, bias transistors 18_{A}, 18_{B} are p-channel enhancement-mode MOS transistors, preferably of minimum channel width (for example, having a width-to-length ratio of on the order of two). The source of transistor 18_{A}is connected to the source/drain region of transistor 14 at the point connected to capacitor 12_{A} and the source of transistor 18_{B} is connected to the source/drain region of transistor 14 at the point connected to capacitor 12_{B}. The gates of transistors 18_{A}, 18_{B} are connected together, and to terminal SW to receive the switching control signal. The drains of transistors 18_{A}, 18_{B} are connected together, and are biased to bias voltage Vₚ.

Because, in this example, transistors 18 are p-channel while transistors 14, 16 are n-channel, transistors 18 are on when transistors 14, 16 are off, and transistors 18 are off when transistors 14, 16 are on. Alternatively, if transistors 14, 16, 18 are all of the same conductivity type, this complementary arrangement may be implemented by applying the logical complement of the signal at terminal SW to the gates of transistors 18. In either case, transistors 18 bias the source/drain regions of transistor 14 from bias voltage Vₚ when transistor 14 is off. As will be described below, bias voltage Vₚ is preferably selected to be at a relatively high voltage (near the V_{CC} power supply in this example), to minimize parasitic capacitance.

In operation, the state of switched variable capacitor 20 is set by the logic level at terminal SW. In this example, the maximum capacitance state is selected by terminal SW being driven to a high logic level. This turns on transistors 14, 16_{A}, 16_{B}, and turns off transistors 18_{A}, 18_{B}. With transistor 14 turned on, capacitors 12_{A}, 12_{B} are connected to one another, presenting the maximum capacitance Cₘₐₓ between terminals A and B. Generally, where capacitors 12_{A}, 12_{B} have capacitances C_{A}, C_{B}, maximum capacitance Cₘₐₓ will be:

$${C}_{max} = \frac{{C}_{A} {C}_{B}}{{C}_{A} + {C}_{B}}$$

$$\text{or, in the special case of} {C}_{A} = {C}_{B} = C \text{:}$$

$${C}_{max} = \frac{C}{2}$$

The source/drain regions of transistor 14 will be biased by transistors 16 toward ground. The effects of this bias by transistors 16 are to maintain the source/drain nodes of transistor 14 from floating, and to minimize the on-resistance of transistor 14, as noted above.

Conversely, in this example, a low logic level at terminal SW will turn off transistor 14, opening the direct connection between capacitors 12_{A}, 12_{B}. In addition, bias transistors 16 are turned off, and bias transistors 18_{A}, 18_{B} are turned on. This state of switched variable capacitor 20 presents the minimum capacitance Cₘᵢₙ between terminals A, B, and biases the source/drain regions of off-state transistor 14 to voltage Vₚ. According to this embodiment of the invention, for example in the case where C_{A}=C_{B}=C, and where capacitors 12_{A}, 12_{B} each have a parasitic capacitance Cₚ′, minimum capacitance Cₘᵢₙ can be evaluated as:

$${C}_{min} = \frac{{CC}_{p}^{′}}{2 ( C + {C}_{p}^{′} )}$$

Parasitic capacitance Cₚ′ depends upon the voltage Vₚ, as will now be discussed.

As described above, in this embodiment of the invention, the parasitic capacitance Cₚ′ for each of capacitors 12_{A}, 12_{B} is the sum of its junction capacitance Cⱼ at the junction between each of the source/drain regions of transistor 14 and the underlying substrate or well, plus the bottom capacitance C_{b} between the capacitor bottom plate and the integrated circuit substrate. For a reverse-biased p-n junction, the junction capacitance Cⱼ decreases with increases in the reverse bias voltage V_{R} across the junction:

$${C}_{j} ∝ \frac{1}{\sqrt{{V}_{R} + {V}_{bi}}}$$

where V_{bi} is the built-in voltage across the junction. As evident from this expression, the reverse bias voltage V_{R} increases, the junction capacitance Cⱼ decreases; this relationship is due to the increase of the space-charge region at the reverse-biased junction with increasing reverse bias. For an n-channel device such as transistor 14, the junction capacitance is reduced with a positive voltage applied to the n-type source/drain regions. According to the preferred embodiment of the invention, therefore, bias voltage Vₚ is preferably as high a voltage as available, for example at the V_{CC} power supply to the integrated circuit embodying switched variable capacitor 20.

Bias transistors 18_{A}, 18_{B} thus provide the important benefit of minimizing the parasitic junction capacitance Cⱼ, and thus reducing the parasitic capacitance C_{P}′ that is presented to each of capacitors 12 in switched variable capacitor 20, by providing the optimal junction bias to the source/drain regions of transistor 14, when in the off-state. Additionally, by implementing bias transistors 18 to have as small a channel width/length ratio as possible, resulting in a relatively high on-resistance through transistors 18, the quality factor Q of switched variable capacitor 20 is degraded as little as possible.

A reduction in junction capacitance Cⱼ is of course reflected in a reduction in the parasitic capacitance Cₚ′ presented to capacitors 12 when switching transistor 14 is off. Recalling that, for the case of C_{A}=C_{B}=C, the ratio of maximum capacitance Cₘₐₓ/Cₘᵢₙ is:

$$\frac{{C}_{max}}{{C}_{min}} = \frac{C + {C}_{p}^{′}}{{C}_{p}^{′}}$$

a reduction in the parasitic capacitance Cₚ′ will result in a geometric increase in the ratio Cₘₐₓ/Cₘᵢₙ. An increase in this ratio provides important benefits in the implementation of switched variable capacitor 20 into an array, as the range and resolution of the switched capacitor array improves with increases in this ratio.

In addition, it is contemplated that the temperature stability of switched variable capacitor 20, particularly in its minimum capacitance state (transistor 14 off) is greatly improved by this invention. The relation of junction capacitance Cⱼ:

$${C}_{j} ∝ \frac{1}{\sqrt{{V}_{R} + {V}_{bi}}}$$

indicates that as reverse bias voltage V_{R} increases, the dependence of junction capacitance Cⱼ on the built-in voltage V_{bi} decreases. The built-in voltage V_{bi} is dependent on temperature, while the reverse bias voltage V_{R} applied by bias transistors 18 can be regulated (by an on-chip voltage regulator, band-gap reference circuit, or the like) to be stable with temperature. As a result, an increase in the reverse bias voltage V_{R} can reduce the temperature sensitivity of junction capacitance Cⱼ. Because bias transistors 18 can apply a stable, high magnitude, reverse bias voltage V_{R} across the source/drain junctions of transistor 14, the junction capacitance Cⱼ can therefore be made significantly more stable over temperature than according to conventional circuits. Stability of parasitic capacitance Cₚ′ over temperature thus translates into temperature stability of the minimum capacitance Cₘᵢₙ, which depends on parasitic capacitance Cₚ′:

$${C}_{min} = \frac{{CC}_{p}^{′}}{2 ( C + {C}_{p}^{′} )}$$

The capacitance of switched variable capacitor 20 in the minimum capacitance state (transistor 14 off) is therefore rendered more stable by the present invention.

Of course, the capacitance of switched variable capacitor 20 in the maximum capacitance state is dependent almost exclusively on the capacitance of each of capacitors 12. According to this invention, the temperature stability of this capacitance is optimized by implementing capacitors 12 as metal-to-metal capacitors, as these devices exhibit extremely low temperature coefficients (e.g., on the order of 10 ppm/° C.).

According to this invention, therefore, a switched variable capacitor is provided that is suitable for use in high-frequency, high performance, applications such as may be used in modern communications systems and devices. For example, it is contemplated that this invention can provide a switched variable capacitor having a high quality factor Q, for example greater than 30, at frequencies on the order of 2.5 GHz, with a tuning range, or capacitance ratio Cₘₐₓ/Cₘᵢₙ, of greater than two.

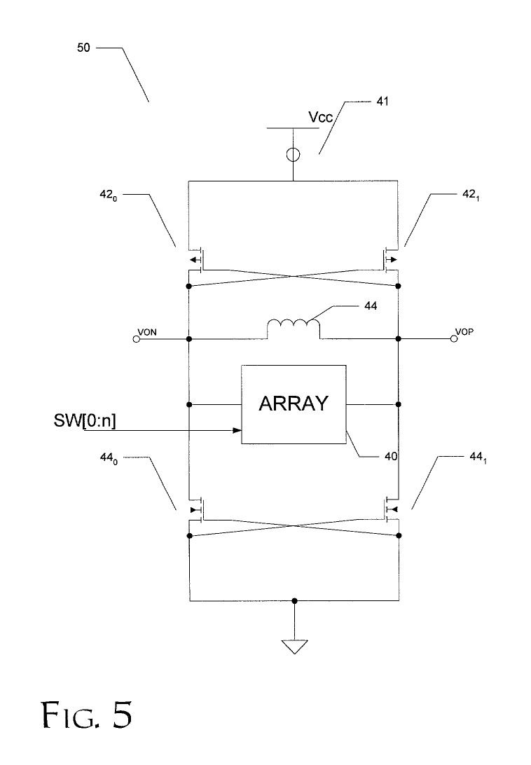

Referring now to FIG. 4, an exemplary implementation of switched variable capacitor 20 into binary-weighted capacitor array 40 will now be described. As noted above, switched variable capacitor 20 is well-suited for implementation into a digitally controlled array 40, to provide a variable capacitance useful in tuning digital circuits and systems. According to this embodiment of the invention, array 40 arranges switched variable capacitors 20, all of a unit maximum capacitance Cₘₐₓ, and thus with all capacitors 20 (including both the capacitors 12 and the transistors 14, 16, 18 ) of identical size, into an array. Such unit sizing can result in an efficient circuit layout.

Binary weighted array 40 of FIG. 4 presents a variable capacitance between terminals A, B, with the capacitance varying according to the digital value on control lines SW. In this example, control lines SW[0:3] present four digital bits, ranging from least significant bit SW[0] to most significant bit SW[3]. Accordingly, a single unit capacitance presented by a single switched variable capacitor 20 as described above is connected between terminals A, B, and is controlled by least significant control bit SW[0] (and corresponds to variable capacitance 30₀). Variable capacitance 30₁, includes two switched variable capacitors 20, both of unit size and thus identical to capacitor 20 in capacitance 30₀, connected in parallel between terminals A, B, and both controlled by control bit SW[1]. Accordingly, variable capacitance 30₁, has a maximum capacitance that is twice that of variable capacitance 30₀; control line SW[1] thus has twice the weight of control line SW[0]. Similarly, the next most significant control bit SW[2] controls variable capacitance 30₂, which includes four switched variable capacitors 20, all of unit capacitance and connected in parallel between terminals A, B. In this four-bit example, most significant control line SW[3] controls variable capacitance 30₃, which consists of eight switched variable capacitors 20, of unit capacitance, connected in parallel between terminals A, B.

In operation, the value of capacitance presented by array 40 between terminals A, B is controlled by the digital value on the four bits of control lines SW[0:3]. Each of variable capacitances 30 for which its associated control line SW is low, in this example, presents a capacitance corresponding to the minimum capacitance Cₘᵢₙ of switched variable capacitor 20, times the number of capacitors 20 in its stage; conversely, each of variable capacitances 30 receiving a high level on its associated control line SW presents a capacitance between terminals A, B corresponding to the maximum capacitance Cₘₐₓ of its switched variable capacitors 20, times the number of capacitors 20 in that stage. Accordingly, binary weighted array 40 according to this embodiment of the invention provides a digitally controlled variable capacitance that has a sizable dynamic range. Additionally, the time and temperature stability discussed above for an individual capacitor 20 is achieved by array 40 on this larger scale. The unit capacitor implementation of array 20 is also conducive to efficient chip layout.

As noted above, binary-weighted array 40 of switched variable capacitor 20 according to the present invention is particularly useful in connection with high-frequency, high performance, circuit applications. One example of such an application is a voltage controlled oscillator (VCO). Referring now to FIG. 5, VCO 50 constructed according to the preferred embodiment of the invention will now be described, by way of example.

In this example, VCO 50 is a digitally-controlled oscillator that generates a periodic signal across its terminals VON, VOP, at a frequency controlled by the value of the digital word presented on control lines SW[0:n]. For the example in which VCO 50 is implemented in a phase-locked loop, this digital word corresponds to the output from a phase-frequency detector. This output is an error signal based upon a comparison of a feedback signal from VCO 50 itself (divided down in frequency if desired) to a reference clock signal. In this case, VCO 50 is controlled by the digital word corresponding to this error signal to modulate its output in a direction that brings the feedback signal closer to a match with the reference clock. Of course, VCO 50 may be used in other applications besides phase-locked loops, such other applications including signal generators, tuning circuits, and the like.

VCO 50 of FIG. 5 is arranged as a conventional L-C CMOS oscillator, with the frequency of oscillation determined by binary weighted array 40, under the control of control lines SW. Current source 41 is coupled between the V_{CC} power supply and the sources of cross-coupled p-channel transistors 42₀, 42₁. The drain of transistor 42₀ is connected to output terminal VON and to the gate of transistor 42₁, while the drain of transistor 42₁, is connected to output terminal VOP and to the gate of transistor 42₀. N-channel transistors 44₀, 44₁ have their drains connected to terminals VON, VOP, respectively, have their sources biased to ground, and have their gates cross-coupled (the gate of transistor 44₀ is connected to the drain of transistor 44₁, and the gate of transistor 44₁, is connected to the gate of transistor 44₀). The oscillator is completed by inductor 44 and binary-weighted array 40, constructed as described above relative to FIG. 4, connected in parallel with one another between terminals VON, VOP.

In operation, the current sourced by current source 41 is conducted alternately by the legs of VCO 50, in the manner well-known for conventional cross-coupled oscillators. The frequency of oscillation is determined by the inductance of inductor 44, which is fixed in this example, and the capacitance presented by binary-weighted capacitor array 40 responsive to the digital control word on lines SW[0:n]. As conventional in the art, the higher the capacitance presented by array 40, the lower the frequency of oscillation, and vice versa.

As noted above, the dynamic range presented by binary-weighted array 40 of switched variable capacitors 20 provides for a wide tuning range of VCO 50 of FIG. 5. In addition, precise digital control is provided by array 40, particularly when realized by unit capacitances as described above relative to FIG. 4. Also as noted above, switched variable capacitors 20 provide excellent stability over temperature, and over time as array 40 is cycled. These benefits are especially important in precision circuits such as VCO 50, making this circuit suitable for excellent performance in such applications as transmission signal modulation in wireless handsets and the like.

Of course, the present invention may also be implemented, and its benefits obtained, in a wide range of tuning and tunable circuits, and in any application in which a precision variable capacitor is useful.

While the present invention has been described according to its preferred embodiments, it is of course contemplated that modifications of, and alternatives to, these embodiments, such modifications and alternatives obtaining the advantages and benefits of this invention, will be apparent to those of ordinary skill in the art having reference to this specification and its drawings. It is contemplated that such modifications and alternatives are within the scope of this invention as subsequently claimed herein.

We claim:

1. A switched variable capacitor, comprising:
a switching field-effect transistor, having first and second source/drain regions, and having a gate for receiving a control signal;
a first capacitor, connected between a first terminal and the first source/drain region of the switching transistor;
a second capacitor, connected between a second terminal and the second source/drain region of the switching transistor; and
first and second complementary bias transistors, having a conduction path connected between a bias voltage and the first and second source/drain regions of the switching transistor, respectively, and having a gate coupled to the gate of the switching transistor, so that the first and second complementary bias transistors are turned on when the switching transistor is turned off.

2. The capacitor of claim 1, wherein the switching transistor is of a first conductivity type;
and wherein the first and second complementary bias transistors are of a second conductivity type.

3. The capacitor of claim 1, further comprising:
first and second bias transistors, having a conduction path connected between a reference voltage and the first and second source/drain regions of the switching transistor, respectively, each having a gate coupled to the gate of the switching transistor, so that the first and second bias transistors are turned on when the switching transistor is turned on.

4. The capacitor of claim 3, wherein the gates of the first and second complementary bias transistors are coupled to the gate of the switching transistor so that the first and second complementary bias transistors are turned off when the switching transistor and the first and second bias transistors are turned on.

5. The capacitor of claim 3, wherein the channel width/length ratio of the switching transistor is substantially larger than the channel width/length ratios of the first and second complementary bias transistors and the first and second bias transistors.

6. The capacitor of claim 1, wherein the bias voltage is selected to have a polarity and magnitude that strongly reverse-biases the source/drain junctions of the switching transistor.

7. The capacitor of claim 1, wherein the first and second capacitors are metal-to-metal capacitors in an integrated circuit.

8. An array of switched variable capacitors, comprising:
a plurality of capacitances, binary-weighted from a smallest capacitance to a largest capacitance, each of the plurality of capacitances connected between first and second terminals and having a control signal, each of the plurality of capacitances including at least one switched variable capacitor that comprises:
a switching field-effect transistor, having first and second source/drain regions, and having a gate for receiving a control signal;
a first capacitor, connected between a first terminal and the first source/drain region of the switching transistor;
a second capacitor, connected between a second terminal and the second source/drain region of the switching transistor; and
first and second complementary bias transistors, having a conduction path connected between a bias voltage and the first and second source/drain regions of the switching transistor, respectively, and having a gate coupled to the gate of the switching transistor, so that the first and second complementary bias transistors are turned on when the switching transistor is turned off; and
a plurality of control lines, binary-weighted to represent a digital control word, each control line associated with a corresponding one of the plurality of capacitances.

9. The array of claim 8, wherein each of the first and second capacitors are of the same capacitance;
wherein a least significant capacitance, corresponding to the smallest capacitance, includes a single switched variable capacitor controlled by the least significant control line;
wherein the next least significant capacitance, corresponding to the next smallest capacitance, includes a pair of switched variable capacitors connected in parallel between the first and second terminals, and controlled by the next least significant control line;
and wherein more significant capacitances each include a plurality of switched variable capacitors, of a number corresponding to the binary-weighting of its associated control line.

10. The array of claim 8, wherein each switching transistor is of a first conductivity type;
and wherein each of the first and second complementary bias transistors is of a second conductivity type.

11. The array of claim 1, wherein each of the switched variable capacitors further comprises:
first and second bias transistors, having a conduction path connected between a reference voltage and the first and second source/drain regions of the switching transistor, respectively, each having a gate coupled to the gate of the switching transistor, so that the first and second bias transistors are turned on when the switching transistor is turned on;
wherein the gates of the first and second complementary bias transistors are coupled to the gate of the switching transistor so that the first and second complementary bias transistors are turned off when the switching transistor and the first and second bias transistors are turned on.

12. The array of claim 11, wherein the channel width/length ratio of each switching transistor is substantially larger than the channel width/length ratios of the first and second complementary bias transistors and the first and second bias transistors in its switched variable capacitor.

13. The array of claim 8, wherein the bias voltage is selected to have a polarity and magnitude that strongly reverse-biases the source/drain junctions of the switching transistor.

14. The array of claim 8, wherein each of the first and second capacitors are metal-to-metal capacitors in an integrated circuit.

15. A method of digitally controlling a switched variable capacitor, comprising the steps of:
in a maximum capacitance state, turning on a switching transistor connected in series with first and second capacitors between first and second terminals, the first and second capacitors connected to first and second source/drain regions of the switching transistor, respectively; and
in a minimum capacitance state:
turning off the switching transistor; and
turning on complementary bias transistors connected between the first and second source/drain regions of the switching transistor and a bias voltage, the bias voltage selected to strongly reverse bias junctions of the first and second source/drain regions of the switching transistor.

16. The method of claim 15, further comprising, in the maximum capacitance state:
turning on bias transistors connected between the first and second source/ drain regions of the switching transistor and a reference voltage.
